(19) United States
(12) Patent Application Publication
(10) Pub. No.: US 2025/0096215 A1
(43) Pub. Date: Mar. 20, 2025

(54) SEMICONDUCTOR PACKAGE AND METHOD FOR MANUFACTURING THE SAME

(71) Applicant: Samsung Electronics Co., Ltd., Suwon-si (KR)

(72) Inventors: HYUNSOO CHUNG, Suwon-si (KR); KWANG-SOO KIM, Suwon-si (KR); CHI WOO LEE, Suwon-si (KR)

(21) Appl. No.: 18/626,787

(22) Filed: Apr. 4, 2024

(30) Foreign Application Priority Data
Sep. 18, 2023 (KR) 10-2023-0123885

(51) Int. Cl. H01L 25/16; H01L 21/56; H01L 23/00; H01L 23/31; H01L 23/373; H01L 23/498

(52) U.S. Cl. CPC H01L 25/167; H01L 21/56; H01L 23/3121; H01L 23/3738; H01L 23/49838; H01L 24/16; H01L 2224/16145; H01L 2224/16235; H01L 2924/1431

(57) ABSTRACT

A semiconductor package includes a redistribution structure, a semiconductor die on the redistribution structure, one or more memory stacking structures disposed on the redistribution structure, wherein the one or more memory stacking structures and the semiconductor die are arranged side by side on the redistribution structure, an optical engine disposed on the redistribution structure, wherein the optical engine and the semiconductor die are arranged side by side on the redistribution structure, and a heat dissipation structure on the semiconductor die, the one or more memory stacking structures, and the optical engine, wherein levels of upper surfaces of the semiconductor die, the one or more memory stacking structures, and the optical engine are the same.

### CROSS-REFERENCE TO RELATED APPLICATION

This application claims priority to and the benefit of Korean Patent Application No. 10-2023-0123885 filed on Sep. 18, 2023 in the Korean Intellectual Property Office, the entire contents of which are herein incorporated by reference.

### BACKGROUND OF THE INVENTION

### (a) Field of the Invention

The present disclosure relates to a semiconductor package and a manufacturing method thereof.

### (b) Description of the Related Art

Demand for data used in individual electronic devices is increasing, and traffic between data centers and such individual electronic devices is expanding accordingly. Meanwhile, a co-packaged optics (CPO), which includes an optical engine such as an optical transceiver and an integrated circuit, has been developed as a device to process high-bandwidth signals transmitted and received in data centers.

The CPO includes an optical engine used to receive optical signals and convert between optical and electrical signals, and semiconductor chips that process the converted electrical signals and control the optical engine. Currently, the optical engine and the semiconductor chip of the CPO are packaged on an interposer and a redistribution structure. According to such a packaging structure, a distance between the optical engine and the semiconductor chip is long, and a signal transmission process that passes through the interposer and redistribution structure is not optimized, thereby causing power loss during the signal transmission process. In addition, the packaging structure has a drawback of poor thermal characteristics because a heat dissipation path is not secured.

Therefore, there is a need for developing a new package technology to solve the aforesaid problems of the CPO.

### SUMMARY OF THE INVENTION

The level of each upper surface of a semiconductor die, a memory stacking structure, and an optical engine can be made the same, and a heat dissipation structure can be placed on the semiconductor die, the memory stacking structure, and optical engine.

A first bridge die and a second bridge die may be disposed on the redistribution structure and below the semiconductor die, the memory stacking structure, and the optical engine, the semiconductor die and the optical engine can be electrically connected by the first bridge die, and the semiconductor die and the memory stacking structure can be electrically connected by the second bridge die.

According to an embodiment of the present disclosure, a semiconductor package includes a redistribution structure, a semiconductor die on the redistribution structure, one or more memory stacking structures disposed on the redistribution structure, wherein the one or more memory stacking structures and the semiconductor die are arranged side by side on the redistribution structure, an optical engine disposed on the redistribution structure, wherein the optical engine and the semiconductor die are arranged side by side on the redistribution structure, and a heat dissipation structure on the semiconductor die, the one or more memory stacking structures, and the optical engine, wherein levels of upper surfaces of the semiconductor die, the one or more memory stacking structures, and the optical engine are the same.

According to an embodiment of the present disclosure a semiconductor package includes a redistribution structure, a first bridge die and one or more second bridge dies on the redistribution structure, a plurality of conductive posts disposed on the redistribution structure, wherein the plurality of conductive posts, the first bridge die, and the one or more second bridge dies are arranged side by side on the redistribution structure, a first molding member disposed on the redistribution structure and covering the first bridge die, the one or more second bridge dies, and the plurality of conductive posts, a semiconductor die on the first molding member, an optical engine disposed on the first molding member, wherein the optical engine and the semiconductor die are arranged side by side on the first molding member, and wherein the first bridge die electrically connects the semiconductor die to the optical engine, one or more memory stacking structures disposed on the first molding member, wherein the one or more memory stacking structures and the semiconductor die are arranged side by side on the first molding member, and wherein the one or more second bridge dies electrically connect the semiconductor die to the one or more memory stacking structures, a second molding member disposed on the first molding member and covering the semiconductor die, the one or more memory stacking structures, and the optical engine, and a heat dissipation structure on the semiconductor die, the one or more memory stacking structures, and the optical engine, wherein upper surfaces of the semiconductor die, the one or more memory stacking structures, and the optical engine are all the same.

According to an embodiment of the present disclosure, a manufacturing method of a semiconductor package includes forming a plurality of conductive posts on a carrier, mounting a first bridge die and one or more second bridge dies on the carrier, molding the first bridge die, the one or more second bridge dies, and the plurality of conductive posts with a first molding member, wherein the first molding member is disposed on the carrier, mounting a semiconductor die, one or more memory stacking structures, and an optical engine on the first bridge die, the one or more second bridge dies, and the plurality of conductive posts, wherein the first bridge die electrically connects the semiconductor die to the optical engine, the one or more second bridge dies electrically connect the semiconductor die to the one or more memory stacking structures, and levels of upper surfaces of the semiconductor die, the one or more memory stacking structures, and the optical engine are the same, molding the semiconductor die, the one or more memory stacking structures, and the optical engine with a second molding member, wherein the second molding member is disposed on the first molding member, removing the carrier to expose a bottom surface of the first bridge die, bottom surfaces of the one or more second bridge dies, and bottom surfaces of the plurality of conductive posts, forming a redistribution structure on the bottom surface of the first bridge die, the bottom surfaces of the one or more second bridge dies, and the bottom surfaces of the plurality of conductive posts, and attaching a heat dissipation structure on the semiconductor die, the one or more memory stacking structures, and the optical engine.

The level of each upper surface of the semiconductor die, the memory stacking structure, and the optical engine can be made the same, and the heat dissipation structure can be placed on the semiconductor die, the memory stacking structure, and the optical engine. As a result, the heat generated in a lower structure disposed below the heat dissipation structure can be dissipated to the outside through the heat dissipation structure, improving the thermal characteristics of the semiconductor package.

The first bridge die and the second bridge die can be disposed on the redistribution structure and below the semiconductor die, the memory stacking structure, and the optical engine, the semiconductor die and the optical engine can be electrically connected by the first bridge die, and the semiconductor die and the memory stacking structure can be electrically connected by the second bridge die. With such a packaging structure, power efficiency can be increased by reducing power loss occurring during the signal transmission process.

### BRIEF DESCRIPTION OF THE DRAWINGS

FIG. 1 is a cross-sectional view of a semiconductor package 100 according to an embodiment.

FIG. 2 is a top plan view of each device in the semiconductor package of FIG. 1.

FIG. 3 to FIG. 6 are cross-sectional views of a manufacturing method of the optical engine.

FIG. 7 to FIG. 17 are cross-sectional views of a manufacturing method of the semiconductor package of FIG. 1.

FIG. 18 is a cross-sectional view of a semiconductor package 100 according to an embodiment.

FIG. 19 to FIG. 32 are cross-sectional views of a manufacturing method of the semiconductor package of FIG. 18.

### DETAILED DESCRIPTION OF THE EMBODIMENTS

Hereinafter, with reference to the accompanying drawing, several embodiments of present disclosure will be explained in detail such that a person of an ordinary skill can easily practice it in the technical field to which the present disclosure belongs. As those skilled in the art would realize, the described embodiments may be modified in various different ways, all without departing from the spirit or scope of the present disclosure.

In order to clearly describe the disclosure with reference to the drawings, parts not related to the description are omitted, and similar reference numerals are designated to similar parts throughout the specification.

In addition, the size and thickness of each component shown in the drawing are arbitrarily indicated for convenience of description and thus the present disclosure is not necessarily limited to what is shown.

Throughout this specification and the claims that follow, when it is described that an element is “coupled” to another element, it includes not only “directly connected”, but also “indirectly connected” between other members. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Furthermore, when an element is “on” or “above” a reference portion, the element is located above or below the reference portion, and it does not necessarily mean that the element is located “on” or “above” in a direction opposite to gravity.

Furthermore, throughout the specification, the phrase “on a plane” means viewing a target portion from the top, and the phrase “on a cross-section” means viewing a cross-section formed by vertically cutting a target portion from the side.

Hereinafter, a semiconductor package 100 and a manufacturing method of the semiconductor package 100 according to an embodiment will be described with reference to the accompanying drawings.

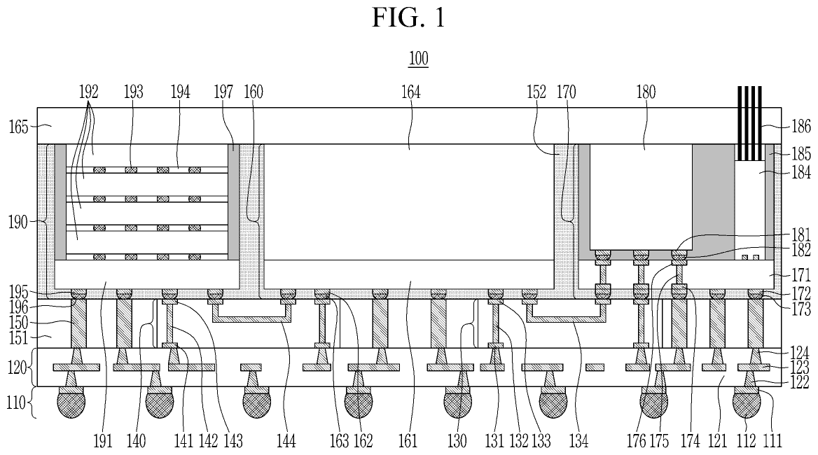

FIG. 1 is a cross-sectional view of a semiconductor package 100 according to an embodiment.

Referring to FIG. 1, a semiconductor package 100 includes an external connection structure 110, a redistribution structure 120, a first bridge die 130, second bridge dies 140, conductive posts (connection members; 150), a first molding member 151, a semiconductor die 160, an optical engine 170, memory stacking structures 190, a second molding member 152, and a heat dissipation structure 165. In an embodiment, the semiconductor package 100 may include a fan out wafer level package (FOWLP) or a fan out panel level package (FOPLP).

The external connection structure 110 is disposed on a bottom surface of the redistribution structure 120. The external connection structure 110 may include conductive pads 111 and external connection members 112. The conductive pad 111 electrically connects a first redistribution via 122 of the redistribution structure 120 to the external connection member 112. The external connection member 112 electrically connects the semiconductor package 100 to an external device.

The redistribution structure 120 may include a dielectric material layer 121, and first redistribution vias 122, first redistribution lines 123, and second redistribution vias 124, which are disposed in the dielectric material layer 121. In an embodiment, a redistribution structure 120 including fewer or more redistribution lines and redistribution vias may be included in the scope of the present disclosure.

The dielectric material layer 121 protects and insulates the first redistribution vias 122, the first redistribution lines 123, and the second redistribution vias 124. The first bridge die 130, the second bridge die 140, the conductive posts 150, and the first molding member 151 are disposed on an upper surface of the first dielectric material layer 121. The external connection structure 110 is placed on a bottom surface of the dielectric material layer 121.

The first redistribution via 122 is disposed between the first redistribution line 123 and the conductive pad 111. The first redistribution via 122 electrically connects the first redistribution line 123 to the external connection member 112 connected to the conductive pad 111 in a vertical direction, which is perpendicular to an upper surface of the redistribution structure 120. The first redistribution line 123 is disposed between the first redistribution via 122 and the second redistribution via 124. The first redistribution line 123 electrically connects the first redistribution via 122 to the second redistribution via 124 in a horizontal direction, which is parallel to the upper surface of the redistribution structure 120. For example, the first redistribution line 123 extends in the horizontal direction, connecting the second redistribution via 124 to the first redistribution via 122. The second redistribution via 124 is disposed between the conductive post 150 and the first redistribution line 123, between the first lower connection pad 131 and the first redistribution line 123, and between the second lower connection pad 141 and the first redistribution line 123. The second redistribution via 124 electrically connects the conductive post 150 to the first redistribution line 123, the first lower connection pad 131 to the first redistribution line 123, and the second lower connection pad 141 to the first redistribution line 123 in the vertical direction.

The first bridge die 130 electrically connects the semiconductor die 160 to the optical engine 170 in the horizontal direction, and electrically connects the optical engine 170 to the redistribution structure 120 and the semiconductor die 160 to the redistribution structure 120 in the vertical direction.

The first bridge die 130 includes first lower connection pads 131, first through-hole silicon vias (TSV) 132, first upper connection pads 133, and first upper connection lines 134. In an embodiment, the first bridge die 130 may include a silicon bridge. A side surface of the first bridge die 130 is covered with the first molding member 151. For example, the first molding member 151 may surround the side surface of the first bridge die 130. The first through-hole silicon via (TSV) 132 included in the first bridge die 130 quickly moves data in the vertical direction, and the first upper connection lines 134 quickly moves data in the horizontal direction. For example, the first through-hole silicon via (TSV) 132 included in the first bridge die 130 may serve as a shorter vertical signal path for transferring data in the vertical direction, and the first upper connection lines 134 may serve as a shorter horizontal signal path for transferring data in the horizontal direction. Therefore, a signal transmission path between the semiconductor die 160 and the optical engine 170 and between the semiconductor die 160 and the redistribution structure 120 can be optimized (i.e., reduced), thereby reducing power consumption and improving the performance of the semiconductor package.

The first lower connection pad 131 is disposed between the second redistribution via 124 of the redistribution structure 120 and the first through-hole silicon via (TSV) 132, and electrically connects the first through-hole silicon via (TSV) 132 to the second redistribution via 124 of the redistribution structure 120.

The first through-hole silicon via (TSV) 132 is disposed between the first lower connection pad 131 and the first upper connection pad 133, and electrically connects the semiconductor die 160 connected to the first upper connection pad 133 to the redistribution structure 120 connected to the first lower connection pad 131 in the vertical direction.

The first upper connection pad 133 is disposed between the first through-hole silicon via (TSV) 132 and a first connection member 163 and between the first through-hole silicon via (TSV) 132 and the second connection member 173, and electrically connects the first connection member 163 and the second connection member 173 to the first through-hole silicon via (TSV) 132 and the first connection member 163 and the second connection member 173 to the first upper connection line 134.

The first upper connection line 134 is disposed between the first upper connection pads 133, and electrically connects the semiconductor die 160 connected to the first upper connection pad 133 to the optical engine 170 connected to the first upper connection pad 133 in the horizontal direction.

In an embodiment, the first through-hole silicon via 132 may include or may be formed of at least one of tungsten, aluminum, copper, and an alloy thereof. In an embodiment, the first lower connection pad 131 and the first upper connection pad 133 each may include or may be formed of at least one of copper, aluminum, silver, tin, gold, nickel, lead, titanium, and an alloy thereof. In an embodiment, the first upper connection line 134 may include or may be formed of at least one of copper, aluminum, silver, tin, gold, nickel, lead, titanium, tungsten, and an alloy thereof.

The second bridge die 140 electrically connects the semiconductor die 160 to the memory stacking structure 190 in the horizontal direction, electrically connects the memory stacking structure 190 to the redistribution structure 120 in the vertical direction, and electrically connects the semiconductor die 160 to the redistribution structure 120 in the vertical direction.

The second bridge die 140 includes second lower connection pads 141, second through-hole silicon vias 142, second upper connection pads 143, and second upper connection lines 144. In an embodiment, the second bridge die 140 may include a silicon bridge. A side surface of the second bridge die 140 is covered with the first molding member 151. For example, the first molding member 151 may surround the side surface of the second bridge die 140. The second through-hole silicon via 142 included in the second bridge die 140 quickly moves data in the vertical direction, and the second upper connection line 144 quickly moves data in the horizontal direction. For example, the second through-hole silicon via 142 may serve as a shorter vertical signal path for transferring data in the vertical direction, and the second upper connection line 144 may serve as a shorter horizontal signal path for transferring data in the horizontal direction. Therefore, a signal transmission path between the semiconductor die 160 and the memory stacking structure 190 and between the semiconductor die 160 and the redistribution structure 120 can be optimized (i.e., reduced), thereby reducing power consumption and improving the performance of the semiconductor package.

The second lower connection pad 141 is disposed between the second redistribution via 124 of the redistribution structure 120 and the second through-hole silicon via 142, and electrically connects the second through-hole silicon via 142 to the second redistribution via 124 of the redistribution structure 120.

The second through-hole silicon via 142 is disposed between the second lower connection pad 141 and the second upper connection pad 143, and electrically connects the semiconductor die 160 connected to the second upper connection pad 143 to the redistribution structure 120 connected to the second lower connection pad 141 in the vertical direction.

The second upper connection pad 143 is disposed between the second through-hole silicon via 142 and the first connection member 163 and between the second through-hole silicon via 142 and the third connection member 196, and electrically connects the first connection member 163 and the third connection member 196 to the second through-hole silicon via 142 and the first connection member 163 and the third connection member 196 to the second upper connection line 144.

The second upper connection line 144 is disposed between the second upper connection pads 143, and electrically connects the semiconductor die 160 connected to the second upper connection pad 143 to the memory stacking structure 190 connected to the second upper connection pad 143 in the horizontal direction.

In an embodiment, the second through-hole silicon via 142 may include or may be formed of at least one of tungsten, aluminum, copper, and alloy thereof. The second lower connection pad 141 and the second upper connection pad 143 each may include or may be formed of at least one of copper, aluminum, silver, tin, gold, nickel, lead, titanium, and an alloy thereof. The second upper connection line 144 may include or may be formed of at least one of copper, aluminum, silver, tin, gold, nickel, lead, titanium, tungsten, and an alloy thereof.

According to the present disclosure, the first bridge die 130 and the second bridge die 140 may be used to electrically connect the lower redistribution structure 120 to the upper semiconductor die 160, the optical engine 170, and the memory stacking structure 190. The first bridge die 130 may electrically connect the semiconductor die 160 to the optical engine 170. The second bridge die 140 may electrically connect the semiconductor die 160 to the memory stacking structure 190. Accordingly, compared to using an interposer for connecting various constituent members with each other, the size of the semiconductor package can be reduced.

The conductive posts 150 are disposed on an upper surface of the redistribution structure 120. The conductive posts 150 are arranged around the first bridge die 130 and the second bridge die 140. The conductive post 150 is disposed below the semiconductor die 160, the optical engine 170, and the memory stacking structure 190. The conductive post 150 electrically connects the first connection member 163, the second connection member 173, and the third connection member 196 to the second redistribution via 124 of the redistribution structure 120. The conductive post 150 is disposed to penetrate the first molding member 151. A side surface of the conductive post 150 is surrounded by the first molding member 151.

The first molding member 151 covers the first bridge die 130, the second bridge die 140, and the conductive posts 150 on the redistribution structure 120. The first molding member 151 may protect the first bridge die 130, the second bridge die 140, and the conductive posts 150 from external environments, and accordingly the semiconductor package 100 may secure electrical or mechanical stability.

The semiconductor die 160 is disposed on the first molding member 151. The semiconductor die 160 is surrounded by the second molding member 152. The semiconductor die 160 includes a logic die 161, first connection pads 162, first connection members 163, and a dummy die 164. In an embodiment, the logic die 161 may include an XPU. The XPU is a processing unit such as a system on chip (SoC), a central processing unit (CPU), a graphic processing unit (GPU), a field programmable gate array (FPGA), an application specific integrated circuit (ASIC), and an Al accelerator. The XPU includes a function to select an appropriate processor for each task using software. In an embodiment, the logic die 161 may include at least one of a Central Processing Unit and a Graphic Processing Unit. The semiconductor die 160 is electrically connected to the first bridge die 130, the second bridge die 140, and the conductive posts 150 through the first connection pads 162 and the first connection members 163.

The first connection pad 162 is disposed between the logic die 161 and the first connection member 163. The first connection pad 162 electrically connects the logic die 161 to the first connection member 163. The first connection member 163 is disposed between the first connection pad 162 and the first upper connection pad 133, between the first connection pad 162 and the second upper connection pad 143, and between the first connection pad 162 and the conductive posts 150. The first connection member 163 electrically connects the first connection pad 162 to the first upper connection pad 133, the first connection pad 162 to the second upper connection pad 143, and the first connection pad 162 to the conductive post 150. In an embodiment, the first connection pad 162 may include or may be formed of at least one of copper, nickel, zinc, gold, silver, platinum, palladium, chromium, titanium, and an alloy thereof. In an embodiment, the first connection member 163 may be a micro bump. In an embodiment, the first connection member 163 may include or may be formed of at least one of tin, silver, lead, nickel, copper, and an alloy thereof

The dummy die 164 is disposed on the logic die 161. The dummy die 164 may have a height such that the levels of each upper surface of the dummy die 164, the optical engine 170, and the memory stacking structure 190 are consistent. For example, the dummy die 164 may serve as a height adjuster of the semiconductor die 160 so that a top surface of the semiconductor die 160 is coplanar with a top surface of the optical engine 170 and a top surface of the memory stacking structure 190. A bottom surface of the dummy die 164 contacts a top surface of the logic die 161. The dummy die 164 covers at least a part of the top surface of the logic die 161. Side surfaces of the dummy die 164 are surrounded by the second molding member 152. In an embodiment, the dummy die 164 may be manufactured from a bare wafer. In an embodiment, the dummy die 164 may include or may be formed of crystalline silicon. Compared to epoxy molding compound (EMC), which is the main material of the second molding member 152, the thermal conductivity of silicon has a much higher value. In an embodiment, the dummy die 164 may include or may be formed of metal with high thermal conductivity, such as copper and aluminum, and thus heat generated within the semiconductor package 100 may be effectively dissipated to the outside through the dummy die 164. The term “contact,” as used herein, refers to a direct connection (i.e., physical touching) unless the context indicates otherwise.

The optical engine 170 is disposed on the first molding member 151. The optical engine 170 is surrounded by the second molding member 152. The optical engine 170 includes photonic integrated circuits (PIC) 171, electron integrated circuits (EIC) 180, a connector 184, and a third molding member 185. A top surface of the optical engine 170 may have the same level as the level of a top surface of each of the semiconductor die 160 and the memory stacking structure 190.

The PIC 171 is placed on the first molding member 151 and positioned at the bottom of the optical engine 170. The PIC 171 includes second connection pads 172, second connection members 173, third lower connection pads 174, third through-hole silicon vias 175, and third upper connection pads 176.

The PIC 171 detects, receives, and processes an optical signal from an optical fiber 186, converts the optical signal to a current signal, and transmits the current signal to the EIC 180. The PIC 171 may be connected to the optical fiber 186 via the connector 184. In an embodiment, the PIC 171 may include at least one of an optical waveguide, an optical modulator, a photo detector (PD), a grating coupler, and a laser diode.

The second connection pads 172 are disposed between the second connection members 173 and the third lower connection pads 174

The second connection pad 172 electrically connects the third lower connection pad 174 to the second connection member 173. The second connection members 173 are disposed between the first upper connection pads 133 of the first bridge die 130 and the second connection pads 172 and between the conductive posts 150 and the second connection pads 172. The second connection members 173 electrically connect the second connection pad 172 to the first upper connection pad 133 of the first bridge die 130 and the second connection pad 172 to the conductive post 150. In an embodiment, the second connection pad 172 may include and may be formed of at least one of copper, nickel, zinc, gold, silver, platinum, palladium, chromium, titanium, and an alloy thereof. In an embodiment, the second connection member 173 may be a micro bump. In an embodiment, the second connection member 173 may include or may be formed of at least one of tin, silver, lead, nickel, copper, and an alloy thereof.

The third lower connection pads 174 are disposed between the third through-hole silicon vias 175 and the second connection pads 172. The third lower connection pads 174 electrically connect the third through-hole silicon via 175 to the second connection pad 172.

The third through-hole silicon vias 175 are disposed between the third lower connection pads 174 and the third upper connection pads 176. The third through-hole silicon via 175 electrically connects the third upper connection pad 176 to the third lower connection pad 174. A portion of the third through-hole silicon vias 175 electrically connects an electron integrated circuit (EIC) 180 to the logic die 161 through the upper connection line 134 in the first bridge die 130. Another portion of the third through-hole silicon vias 175 electrically connects the EIC 180 to the redistribution structure 120 through the first through-hole silicon vias 132 in the first bridge die 130. Another portion of the third through-hole silicon vias 175 electrically connects the EIC 180 to the redistribution structure 120 through the conductive posts 150.

The third upper connection pads 176 are disposed between the fourth connection members 182 and the third through-hole silicon vias 175. The third upper connection pads 176 electrically connect the fourth connection members 182 to the third through-hole silicon via 175.

In an embodiment, the third through-hole silicon via 175 may include or may be formed of at least one of tungsten, aluminum, copper, and an alloy thereof. The third lower connection pad 174 and the third upper connection pad 176 each may include or may be formed of at least one of copper, aluminum, silver, tin, gold, nickel, lead, titanium, and an alloy thereof.

The EIC 180 is disposed on the PIC 171. The EIC 180 includes fourth connection pads 181 and fourth connection members 182. An upper surface of the EIC 180 has the same level as the level of each upper surface of the semiconductor die 160 and the memory stacking structure 190.

The EIC 180 receives and amplifies a current signal transmitted from the PIC 171 and converts the current signal to a voltage signal. The EIC 180 receives a signal from the logic die 161 and transmits the signal to the PIC 171, and transmits the voltage signal to the logic die 161 via a physical layer transceiver (PHY). In an embodiment, the EIC 180 may include a control circuit for controlling the operation of the PIC 171 according to a signal transmitted from the logic die 161 and a circuit for processing a current signal from the PIC 171. In an embodiment, the EIC 180 may include at least one of a CPU, a controller, and an amplifier.

The fourth connection pads 181 are disposed between an electron integrated circuit base and the fourth connection members 182. The fourth connection pad 181 electrically connects the electron integrated circuit base to the fourth connection member 182. The fourth connection members 182 are disposed between the fourth connection pads 181 and the third upper connection pads 176 of the PIC 171. The fourth connection member 182 electrically connects the fourth connection pad 181 to the third upper connection pad 176 of the PIC 171. In an embodiment, the fourth connection pad 181 may include or may be formed of at least one of copper, nickel, zinc, gold, silver, platinum, palladium, chromium, titanium, and an alloy thereof. In an embodiment, the fourth connection member 182 may be a micro bump. In an embodiment, the fourth connection member 182 may include or may be formed of at least one of tin, silver, lead, nickel, copper, and an alloy thereof.

The connector 184 is disposed on the PIC 171. The connector 184 is connected to the optical fiber 186 and transmits the optical signal from the optical fiber 186 to the PIC 171. A top surface of the connector 184 has the same level as the level of a top surface of each of the semiconductor die 160 and the memory stacking structure 190.

The third molding member 185 covers the EIC 180 and the connector 184 on the PIC 171. In an embodiment, the third molding member 185 may surround a side surface of the EIC 180 and a side surface of the connector 184. The third molding member 185 protects the EIC 180 and the connector 184 from the external environment.

The memory stacking structure 190 is disposed on the first molding member 151. The memory stacking structure 190 is surrounded by the second molding member 152. In an embodiment, the second molding member 152 may surround a side surface of the memory stacking structure 190. The memory stacking structure 190 includes a buffer die 191, stacked core dies 192, interconnection member 193, an insulation member 194, a third connection pad 195, a third connection member 196, and a fourth molding member 197. In an embodiment, the memory stacking structure 190 may include or may be a high bandwidth memory (HBM). A top surface of the memory stacking structure 190 has the same level as the level of a top surface of each of the semiconductor die 160 and the optical engine 170.

The buffer die 191 is placed at the bottom of the memory stacking structure 190. When exchanging data between devices with different data processing speeds, processing units, and usage times, data loss may occur due to differences in data processing speeds, processing units, and usage times between each device. In order to prevent such data loss, the buffer die 191 is disposed between the stacked core dies 192 and the logic die 161, and information when exchanging data between the stacked core dies 192 and the logic die 161 is temporarily stored in the buffer die 191. When transmitting data to the stacked core dies 192 or receiving data from the stacked core dies 192, the buffer die 191 matches the order of the data received and passes the data sequentially.

The stacked core dies 192 are disposed on the buffer die 191. The stacked core dies 192 each include memory channels and through-hole silicon vias. In an embodiment, the core dies 192 may be a DRAM. In an embodiment, high-bandwidth memory containing fewer or more core dies 192 is included in the scope of the present disclosure.

The interconnection members 193 are disposed between the buffer die 191 and the stacked core dies 192 and between the stacked core dies 192. The interconnection member 193 electrically connects the stacked core dies 192 to the buffer die 191, and the stacked core dies 192 with each other. In an embodiment, the interconnection member 193 may include a micro bump. In an embodiment, the interconnection member 193 may include or may be formed of copper.

The insulation member 194 is disposed between the buffer die 191 and the stacked core dies 192 and between the respective stacked core dies 192, thereby surrounding the interconnection member 193. The insulation member 194 relieves stress between the buffer die 191 and the stacked core dies 192, and between each of the stacked core dies 192. In an embodiment, the insulation member 194 may include or may be a non-conductive film (NCF).

The third connection pads 195 are disposed between the buffer die 191 and the third connection members 196. The third connection pad 195 electrically connects the buffer die 191 to the third connection members 196. The third connection members 196 are disposed between the third upper connection pads 143 of the second bridge die 140 and the third connection pads 195 and between the conductive posts 150 and the third connection pads 195. The third connection members 196 electrically connect the third connection pad 195 to the third upper connection pad 143 of the second bridge die 140 and the third connection pad 195 to the conductive post 150. In an embodiment, the third connection pad 195 may include or may be formed of at least one of copper, nickel, zinc, gold, silver, platinum, palladium, chromium, titanium, and an alloy thereof. In an embodiment, the third connection member 196 may be a micro bump. In an embodiment, the third connection member 196 may include or may be formed of at least one of tin, silver, lead, nickel, copper, and an alloy thereof.

The fourth molding member 197 covers the stacked core dies 192 on the buffer die 191. The fourth molding member 197 protects the stacked core dies 192 from the external environment.

The second molding member 152 covers the semiconductor die 160, the optical engine 170, and the memory stacking structures 190 on the first molding member 151. The second molding member 152 protects the semiconductor die 160, the optical engine 170, and the memory stacking structures 190 from the external environment, and accordingly, the semiconductor package 100 can secure electrical or mechanical stability.

The heat dissipation structure 165 is disposed on the second molding member 152. A bottom surface of the heat dissipation structure 165 contacts the top surface of each of the dummy die 164, the EIC 180, the connector 184, and the topmost core die 192. In an embodiment, the heat dissipation structure 165 may be manufactured from a bare wafer. In an embodiment, the heat dissipation structure 165 may include or may be formed of crystalline silicon. Compared to epoxy molding compound (EMC), which is the main material of the second molding member 152, the thermal conductivity of silicon has a much higher value. In an embodiment, the heat dissipation structure 165 may include or may be formed of metal having high heat conductivity, such as copper and aluminum. Accordingly, heat generated within the semiconductor package 100 may be effectively dissipated to the outside through a path passing through the dummy die 164 and the heat dissipation structure 165.

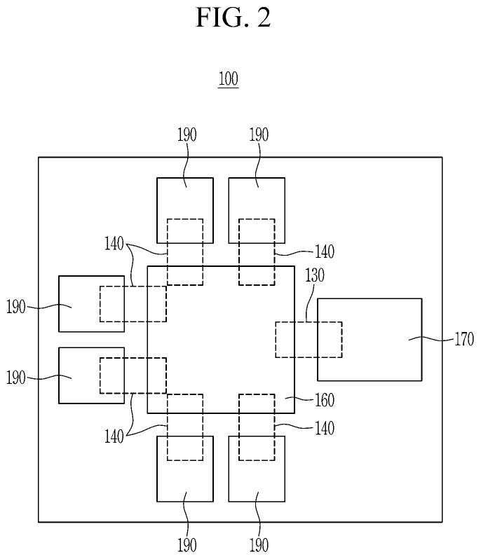

FIG. 2 is a top plan view of each device in the semiconductor package 100 of FIG. 1.

Referring to FIG. 2, when the semiconductor package 100 from which the second molding member 152 and the heat dissipation structure 165 are removed is viewed on a top plan view, the semiconductor die 160 is placed at a center of the semiconductor package 100 and the optical engine 170 and the memory stacking structures 190 are disposed at the periphery of the semiconductor die 160. Since the first bridge die 130 and the second bridge dies 140 are disposed below the bottom surface of each of the semiconductor die 160, the optical engine 170, and the memory stacking structures 190, the outlines of first bridge die 130 and second bridge dies 140 are shown as dotted lines.

The optical engine 170 is disposed next to a first side of the semiconductor die 160. The memory stacking structures 190 are disposed next to the other sides of the semiconductor die 160. The first bridge die 130 electrically connects the semiconductor die 160 to the optical engine 170. The second bridge die 140 electrically connects the semiconductor die 160 to each memory stacking structure 190.

A co-packaged optics (CPO) according to the present disclosure includes a structure in which the semiconductor die 160, the optical engine 170, and the memory stacking structure 190 are electrically connected by a bridge die that can optimize (i.e., reduce) the signal transmission path instead of the interposer used conventionally, and in which the semiconductor die 160 and optical engine 170 are arranged as close as possible. With this packaging structure, power loss occurring during the signal transmission process can be reduced and power efficiency can be increased.

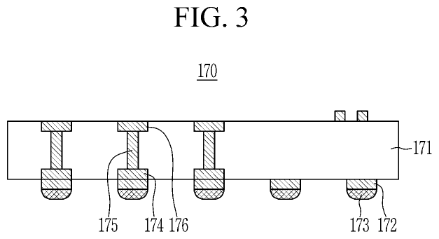

FIG. 3 to FIG. 6 are cross-sectional views of a manufacturing method of the optical engine 170.

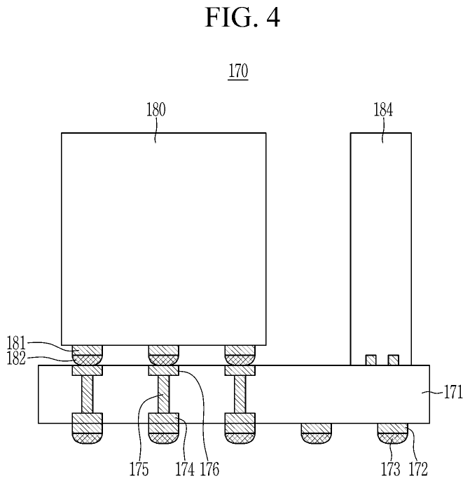

Referring to FIG. 3 and FIG. 4, the PIC 171 is provided, and the EIC 180 and the connector 184 are mounted on the PIC 171. The EIC 180 is placed on the PIC 171 by flip chip bonding. Each of the fourth connection members 182 of the EIC 180 is disposed to be electrically connected to a corresponding one of the third through-hole silicon vias 175.

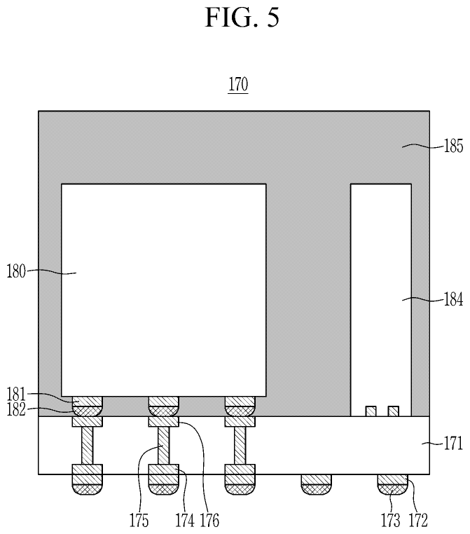

Referring to FIG. 5, the EIC 180 and the connector 184 are molded using the third molding member 185 on the PIC 171. In an embodiment, the molding process with the third molding member 185 may include a compression molding or transfer molding process. In an embodiment, the third molding member 185 may include or may be formed of an epoxy molding compound (EMC).

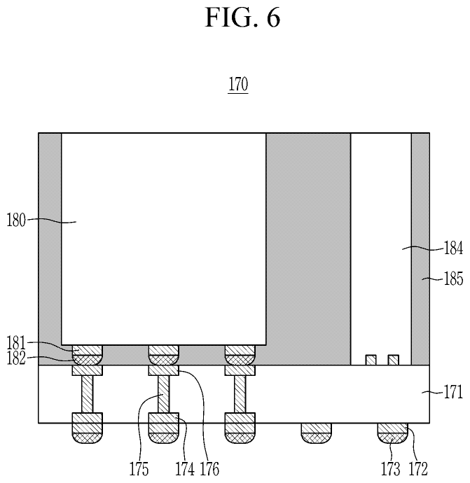

Referring to FIG. 6, chemical mechanical polishing (CMP) is performed to level the upper surface of the third molding member 185. The CMP process is applied to planarize the upper surface of the third molding member 185. After performing the CMP process, the upper surfaces of the EIC 180 and connector 184 are exposed.

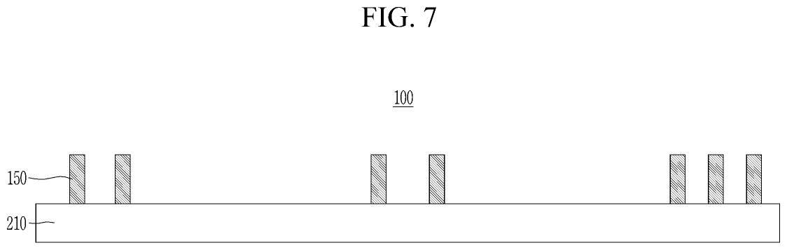

FIG. 7 to FIG. 17 are cross-sectional views of a manufacturing method of the semiconductor package 100 of FIG. 1.

FIG. 7 is a cross-sectional view of forming the conductive posts 150 on the carrier 210.

Referring to FIG. 7, the redistribution structure 120 is formed on the carrier 210. In an embodiment, the carrier 210 may include a silicon-based material such as glass and silicon oxide, an organic material, another material such as aluminum oxide, or any combination of these materials.

The conductive posts 150 is formed in the vertical direction on the carrier 210. In an embodiment, the conductive posts 150 may be formed by performing an electrolytic plating process after forming a seed metal layer. In an embodiment, the conductive posts 150 may be formed by performing a sputtering process. In an embodiment, the conductive post 150 may include or may be formed of at least one of copper, aluminum, tungsten, nickel, gold, silver, chromium, antimony, tin, titanium, and an alloy thereof.

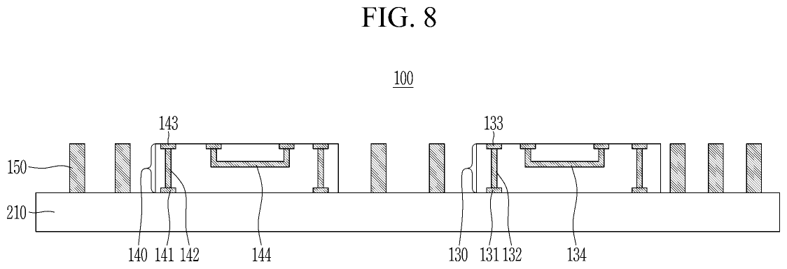

FIG. 8 is a cross-sectional view of attaching the first bridge die 130 and the second bridge dies 140 on the carrier 210.

Referring to FIG. 8, the first bridge die 130 and the second bridge dies 140 are attached on the carrier 210. In an embodiment, the first bridge die 130 and the second bridge dies 140 may be attached by laser.

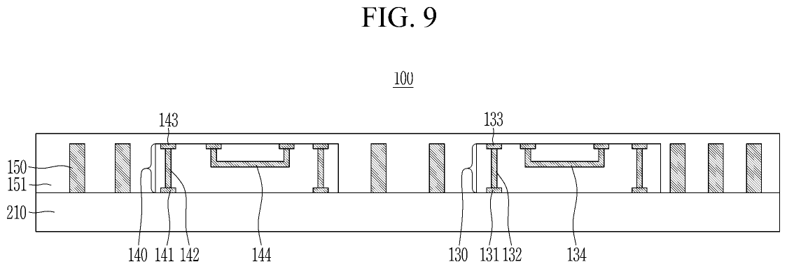

FIG. 9 is a cross-sectional view of molding the first bridge die 130 and the second bridge dies 140 with the first molding member 151 on the carrier 210.

Referring to FIG. 9, the first bridge die 130 and the second bridge dies 140 are molded with the first molding member 151 on the carrier 210. In an embodiment, the molding process with the first molding member 151 may include a compression molding or transfer molding process. In an embodiment, the first molding member 151 may include or may be formed of an EMC.

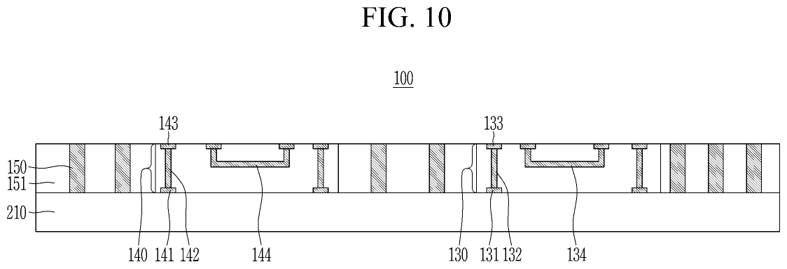

FIG. 10 is a cross-sectional view of planarizing the first molding member 151.

Referring to FIG. 10, the CMP is performed to level the top surface of the first molding member 151. The CMP process is applied to planarize the upper surface of the first molding member 151. After performing the CMP process, the upper surfaces of the conductive posts 150, first bridge die 130, and second bridge die 140 are exposed.

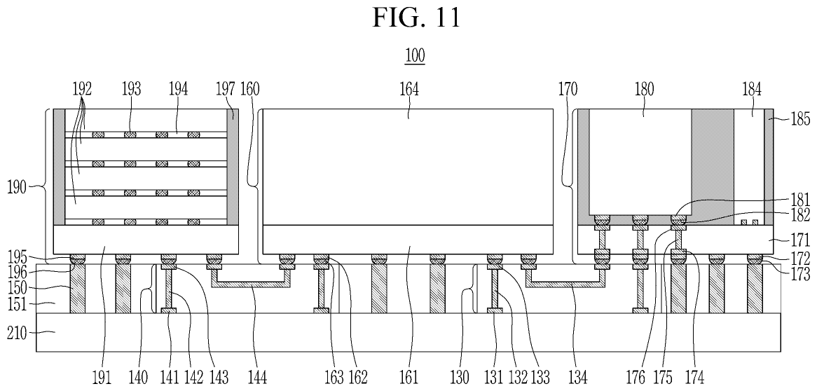

FIG. 11 is a cross-sectional view of mounting the semiconductor die 160, the optical engine 170, and the memory stacking structures 190 on the first bridge die 130, the second bridge dies 140, and the conductive posts 150.

Referring to FIG. 11, the semiconductor die 160, the optical engine 170, and the memory stacking structures 190 are mounted to be electrically connected to the first bridge die 130, the second bridge dies 140, and the conductive posts 150. The semiconductor die 160, the optical engine 170, and the memory stacking structures 190 are each mounted by flip chip bonding.

The first connection members 163 of the semiconductor die 160 are bonded to the first upper connection pads 133 of the first bridge die 130, the second upper connection pads 143 of the second bridge dies 140, and the conductive posts 150, and the semiconductor die 160 is electrically connected to the first bridge die 130, the second bridge dies 140, and the conductive posts 150.

The second connection members 173 of the optical engine 170 are bonded to the first upper connection pads 133 of the first bridge die 130 and the conductive posts 150, and the optical engine 170 is electrically connected to the first bridge die 130 and the conductive posts 150.

The third connection members 196 of the respective memory stacking structures 190 are bonded to the second upper connection pads 143 of the second bridge dies 140 and the conductive posts 150, and the memory stacking structures 190 are electrically connected to the second bridge die 140 and the conductive posts 150.

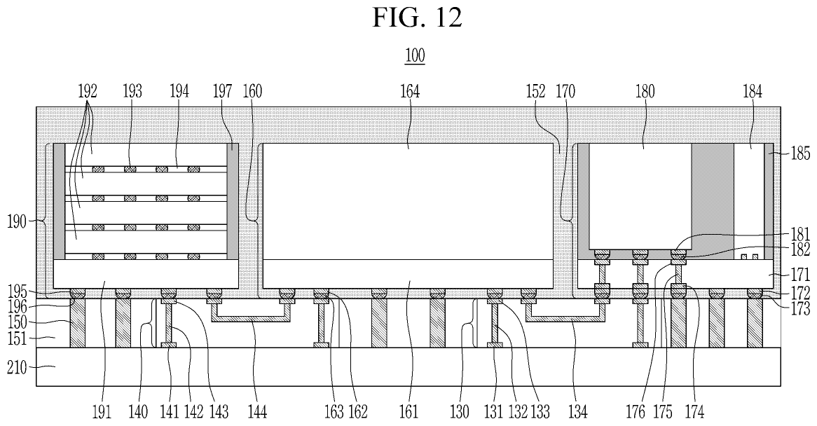

FIG. 12 is a cross-sectional view of molding the semiconductor die 160, the optical engine 170, and the memory stacking structures 190 with the second molding member 152 on the first molding member 151.

Referring to FIG. 12, on the first molding member 151, the semiconductor die 160, the optical engine 170, and the memory stacking structures 190 are molded with the second molding member 152. In an embodiment, the molding process with the second molding member 152 may include a compression molding or transfer molding process. In an embodiment, the second molding member 152 may include or may be formed of an EMC.

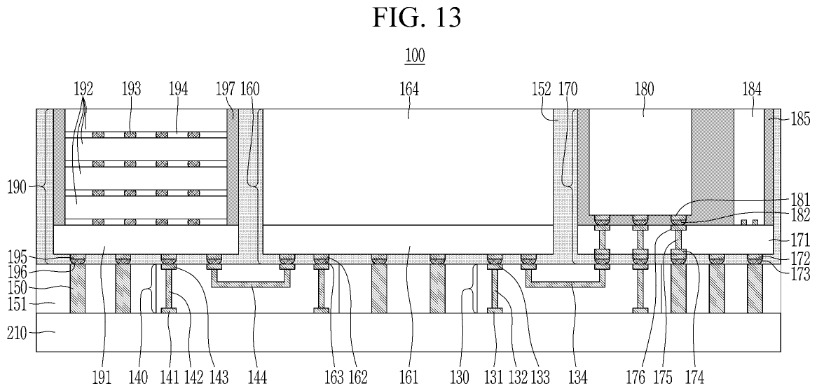

FIG. 13 is a cross-sectional view of planarizing the second molding member 152.

Referring to FIG. 13, the CMP is performed to level the top surface of the second molding member 152. The CMP process is applied to planarize the upper surface of the second molding member 152. After performing the CMP process, the upper surfaces of the semiconductor die 160, the optical engine 170, and the memory stacking structures 190 are exposed. In this case, the levels of the upper surfaces of the second molding member 152, the semiconductor die 160, the optical engine 170, and the memory stacking structures 190 are all the same.

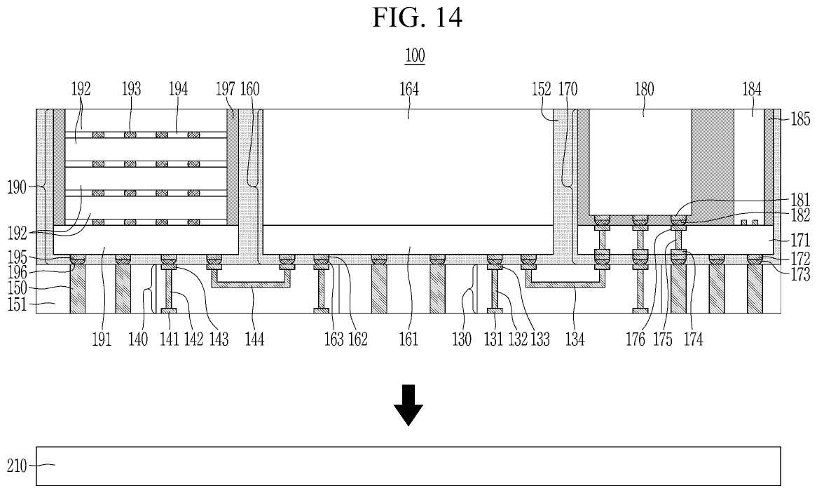

FIG. 14 is a cross-sectional view of removing the carrier 210 from the bottom surface of the first molding member 151.

Referring to FIG. 14, the carrier 210 is removed from the bottom surface of the first molding member 151.

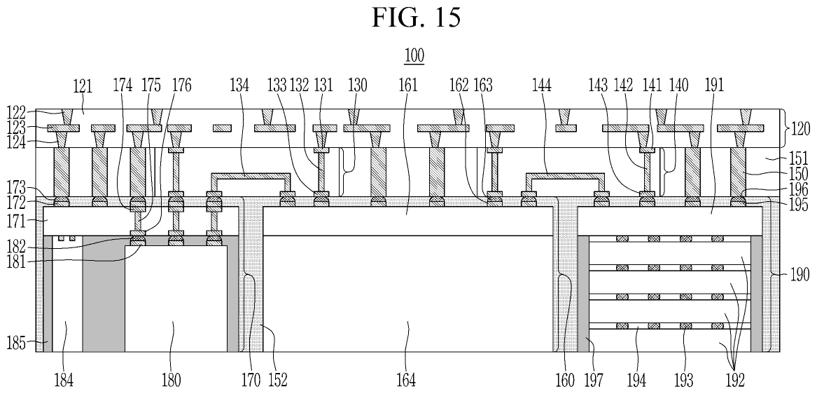

FIG. 15 is a cross-sectional view of forming the redistribution structure 120 on the first bridge die 130, the second bridge dies 140, the conductive posts 150, and the first molding member 151.

Referring to FIG. 15, an intermediate product of semiconductor package 100 is placed upside down, and the redistribution structure 120 is formed on the first bridge die 130, the second bridge dies 140, the conductive posts 150, and the first molding member 151. According to the present disclosure, since the dielectric material layer 121 is directly formed on the first bridge die 130, the second bridge dies 140, the conductive posts 150, and the first molding member 151, a connection member such as a micro bump and a solder bump is not used between the redistribution structure 120 and each of the first bridge die 130, the second bridge dies 140, and the conductive posts 150.

The dielectric material layer 121 is formed on the first bridge die 130, the second bridge dies 140, the conductive posts 150, and the first molding member 151. In an embodiment, the dielectric material layer 121 may include or may be formed of a photoimageable dielectric (PID) used in a redistribution process. The PID is a material that can form a fine pattern by applying a photolithography process. In an embodiment, the PID may include a polyimide-based photoactive polymer, a novolac-based photoactive polymer, polybenzoxazole, a silicon-based polymer, an acrylate-based polymer, or an epoxy-based polymer. In an embodiment, the dielectric material layer 121 may include or may be formed of an inorganic dielectric material such as silicon nitride, silicon oxide, and the like. In an embodiment, the dielectric material layer 121 may be formed by a chemical vapor deposition (CVD), atomic layer deposition (ALD), or plasma enhanced CVD (PECVD) process.

After forming the dielectric material layer 121, via holes are formed by selectively etching the dielectric material layer 121, and the via holes are filled with a conductive material, thereby forming the second redistribution vias 124. Since the second redistribution vias 124 are formed after placing an intermediate product of the semiconductor package 100 upside down, a width of the topmost portion of the second redistribution vias 124 is larger than a width of the bottommost portion thereof. In the final product, the top width of second redistribution vias 124 is smaller than the bottom width.

Next, an additional dielectric layer may be deposited on the second redistribution vias 124 and the dielectric material layer 121. The additionally deposited dielectric material layer 121 is selectively etched to form openings, and the openings are filled with a conductive material, thereby forming the first redistribution lines 123.

Next, An additional dielectric layer may be deposited on the first redistribution lines 123 and the dielectric material layer 121, and the additionally deposited dielectric material layer 121 is selectively etched to form via holes, and the via holes are filled with a conductive material, thereby forming the first redistribution vias 122. For the same reason as for the second redistribution vias 124, in the final product, the top width of first redistribution vias 122 is smaller than the bottom width. For example, the dielectric material layer 121 in the final product may be formed by depositing a dielectric material layer multiple times (e.g., three times).

In an embodiment, the first redistribution vias 122, the first redistribution lines 123, and the second redistribution vias 124 may include or may be formed of at least one of copper, aluminum, tungsten, nickel, gold, tin, titanium, and an alloy thereof. In an embodiment, the first redistribution vias 122, the first redistribution lines 123, and the second redistribution vias 124 may be formed by performing an electrolytic plating process after forming a seed metal layer. In an embodiment, the first redistribution vias 122, the first redistribution lines 123, and the second redistribution vias 124 may be formed by performing a sputtering process.

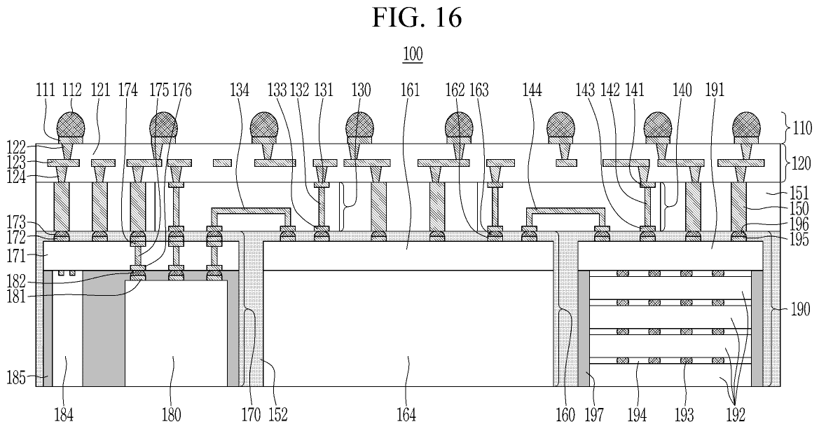

FIG. 16 is a cross-sectional view of forming the external connection structure 110 on the bottom surface of the redistribution structure 120.

Referring to FIG. 16, the external connection structure 110 is formed on the bottom surface of the redistribution structure 120. The conductive pads 111 are formed below the first redistribution vias 122 of the redistribution structure 120, and the external connection members 112 are formed below the conductive pads 111. In an embodiment, the conductive pad 111 may include or may be formed of at least one of copper, nickel, zinc, gold, silver, platinum, palladium, chromium, titanium, and an alloy thereof. In an embodiment, the external connection member 112 may include or may be formed of at least one of tin, silver, lead, nickel, copper, and an alloy thereof. In an embodiment, the conductive pad 111 may be formed by performing a sputtering process, or an electrolytic plating process after forming a seed metal layer.

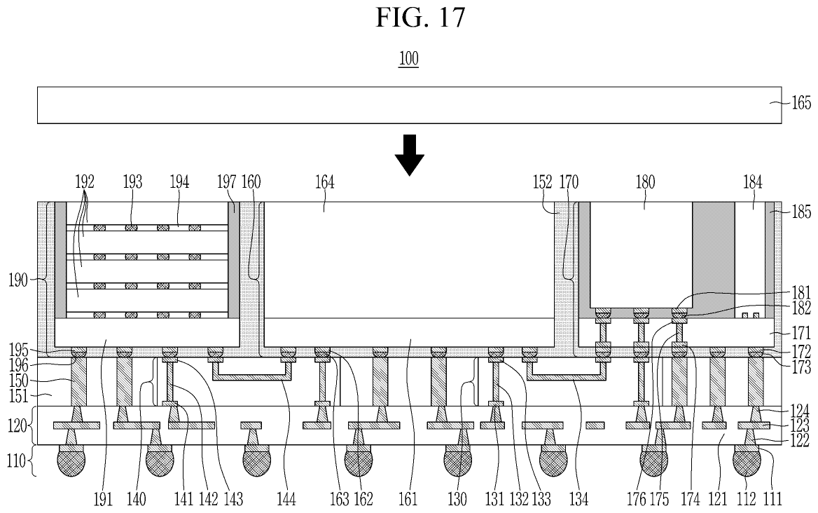

FIG. 17 is a cross-sectional view of attaching the heat dissipation structure 165 on the semiconductor die 160, the optical engine 170, and the memory stacking structures 190.

Referring to FIG. 17, the heat dissipation structure 165 is attached on the semiconductor die 160, the optical engine 170, and the memory stacking structures 190. In an embodiment, the heat dissipation structure 165 is attached using an adhesive member. In an embodiment, the adhesive member may include an adhesive tape, silver paste (Ag paste), epoxy resin, or polyimide. In an embodiment, the heat dissipation structure 165 is attached using a thermal interface material (TIM). In an embodiment, the TIM may include thermal paste, thermal pad, a phase change material (PCM), or a metal material. In an embodiment, the TIM may include grease.

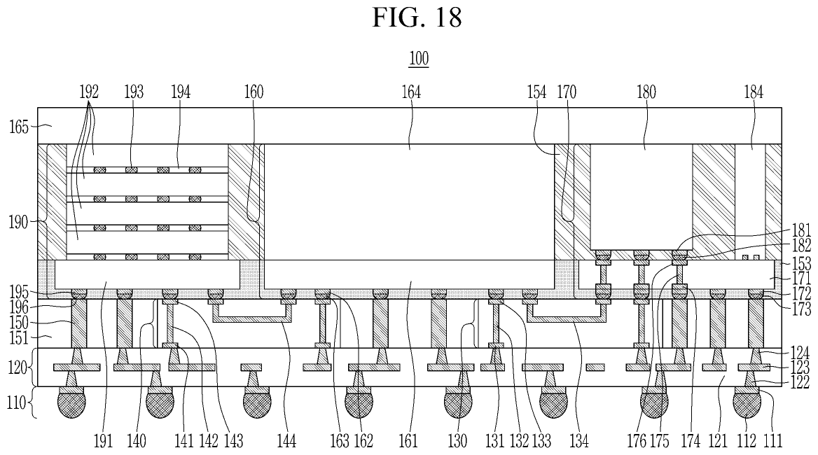

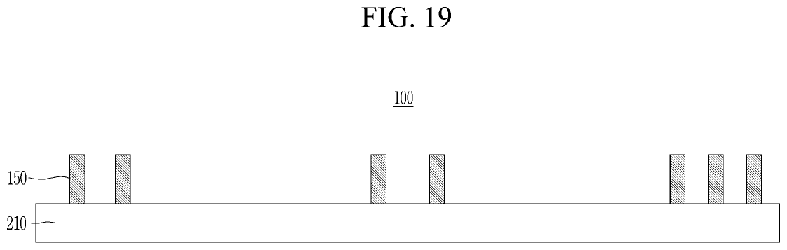

FIG. 18 is a cross-sectional view of a semiconductor package 100 according to an embodiment. FIG. 18 is a cross-sectional view of a semiconductor package 100 manufactured using a manufacturing method of FIG. 19 to FIG. 32.

Referring to FIG. 18, buffer dies 191, a logic die 161, and a PIC 171 are molded by a fifth molding member 153. An upper surface of each of the buffer dies 191, the logic die 161, and the PIC 171 has the same level. Stacked core dies 192, a dummy die 164, an EIC 180, and a connector 184 are molded by a sixth molding member 154. A level of an upper surface of each of the stacked core dies 192, the dummy die 164, the EIC 180, and the connector 184 is the same.

Compared to the semiconductor package 100 of FIG. 1, the stacked core dies 192 of the semiconductor package 100 of FIG. 18 are directly molded by the sixth molding member 154 rather than being molded by a fourth molding member 197, and the EIC 180 and the connector 184 of the of FIG. 18 semiconductor package 100 are directly molded by the sixth molding member 154 rather than being molded by the third molding member 185.

Configurations other than those described above for FIG. 18 are equally applied to the description for FIG. 1.

FIG. 19 to FIG. 32 are cross-sectional views of a manufacturing method of the semiconductor package 100 of FIG. 18.

FIG. 19 is a cross-sectional view of forming conductive posts 150 on a carrier 210.

Referring to FIG. 19, a redistribution structure 120 is formed on the carrier 210. In an embodiment, the carrier 210 may include a silicon-based material such as glass and silicon oxide, an organic material, another material such as aluminum oxide, or any combination of these materials.

The conductive posts 150 is formed in the vertical direction on the carrier 210. In an embodiment, the conductive posts 150 may be formed by performing an electrolytic plating process after forming a seed metal layer. In an embodiment, the conductive posts 150 may be formed by performing a sputtering process. In an embodiment, the conductive post 150 may include or may be formed of at least one of copper, aluminum, tungsten, nickel, gold, silver, chromium, antimony, tin, titanium, and an alloy thereof.

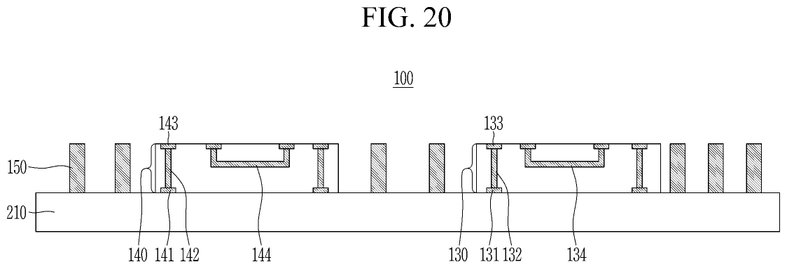

FIG. 20 is a cross-sectional view of attaching the first bridge die 130 and the second bridge dies 140 on the carrier 210.

Referring to FIG. 20, the first bridge die 130 and the second bridge dies 140 are attached on the carrier 210. In an embodiment, the first bridge die 130 and the second bridge dies 140 may be attached by laser.

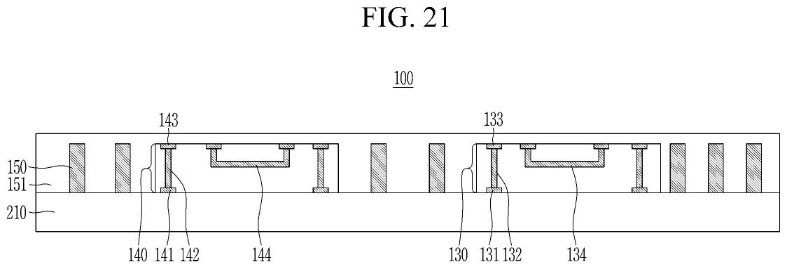

FIG. 21 is a cross-sectional view of molding the first bridge die 130 and the second bridge dies 140 with the first molding member 151 on the carrier 210.

Referring to FIG. 21, the first bridge die 130 and the second bridge dies 140 are molded with the first molding member 151 on the carrier 210. In an embodiment, the molding process with the first molding member 151 may include a compression molding or transfer molding process. In an embodiment, the first molding member 151 may include or may be formed of an epoxy molding compound (EMC).

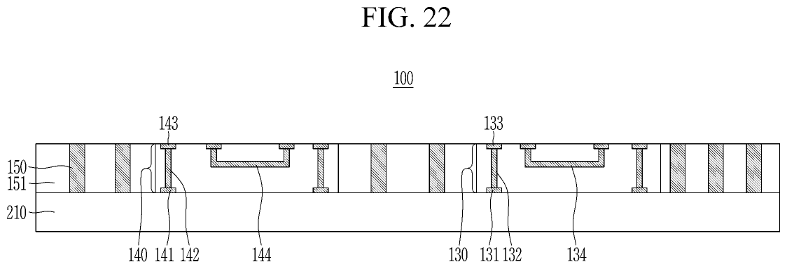

FIG. 22 is a cross-sectional view of planarizing the first molding member 151.

Referring to FIG. 22, the CMP is performed to level the top surface of the first molding member 151. The CMP process is applied to planarize the upper surface of the first molding member 151. After performing the CMP process, the upper surfaces of the conductive posts 150, first bridge die 130, and second bridge die 140 are exposed.

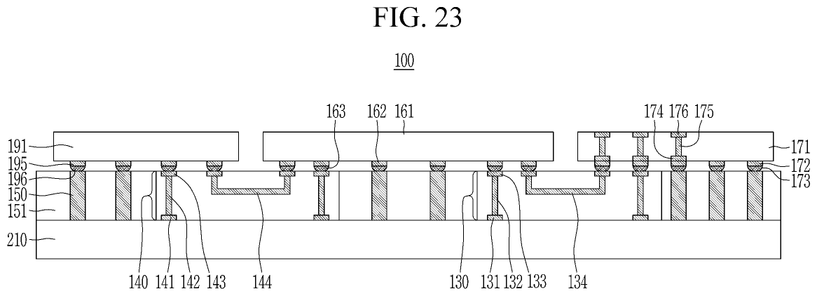

FIG. 23 is a cross-sectional view of mounting the logic die 161, the PIC 171, and the buffer dies 191 on the first bridge die 130, the second bridge dies 140, and the conductive posts 150.

Referring to FIG. 23, the logic die 161, the PIC 171, and the buffer dies 191 are mounted to be electrically connected to the first bridge die 130, the second bridge dies 140, and the conductive posts 150. The logic die 161, the PIC 171, and the buffer dies 191 are each mounted by flip chip bonding.

The first connection members 163 of the logic die 161 are bonded to the first upper connection pads 133 of the first bridge die 130, the second upper connection pads 143 of the second bridge dies 140, and the conductive posts 150, and the logic die 161 is electrically connected to the first bridge die 130, the second bridge dies 140, and the conductive posts 150.

The second connection members 173 of the PIC 171 are bonded to the first upper connection pads 133 of the first bridge die 130 and the conductive posts 150, and the PIC 171 is electrically connected to the first bridge die 130 and the conductive posts 150.

The third connection members 196 of each buffer die 191 are bonded to the second upper connection pads 143 of the second bridge die 140 and the conductive posts 150, and the buffer dies 191 are electrically connected to the second bridge die 140 and the conductive posts 150.

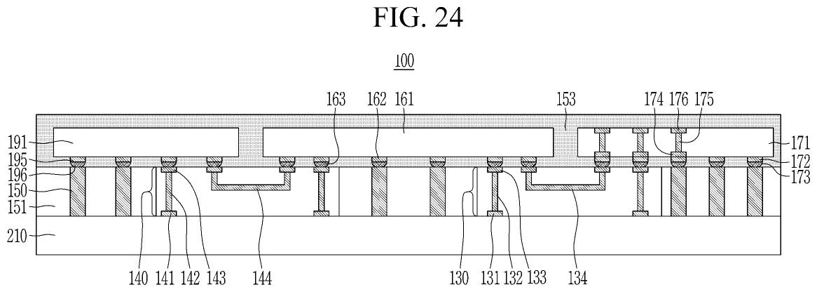

FIG. 24 is a cross-sectional view of molding the logic die 161, the PIC 171, and the buffer dies 191 with a fifth molding member 153 on the first molding member 151.

Referring to FIG. 24, the logic die 161, the PIC 171, and the buffer dies 191 are molded with the fifth molding member 153 on the first molding member 151. In an embodiment, the molding process with the fifth molding member 153 may include a compression molding or transfer molding process. In an embodiment, the fifth molding member 153 may include or may be formed of an EMC.

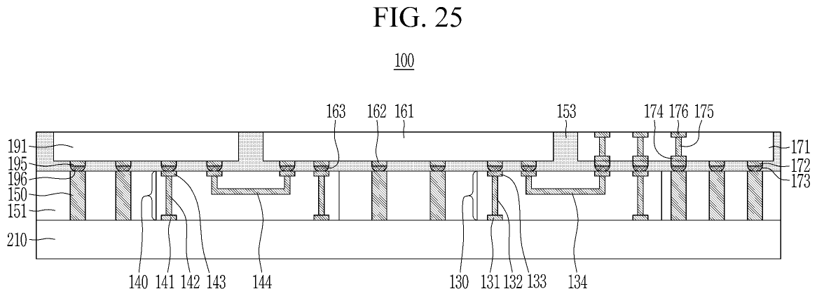

FIG. 25 is a cross-sectional view of planarizing the fifth molding member 153.

Referring to FIG. 25, the CMP process is carried out to planarize an upper surface of the fifth molding member 153. The CMP process is applied to planarize the upper surface of the fifth molding member 153. After performing the CMP process, the upper surfaces of the logic die 161, the PIC 171, and the buffer dies 191 are exposed. In this case, the levels of the upper surfaces of the logic die 161, the PIC 171, and the buffer dies 191 are all the same.

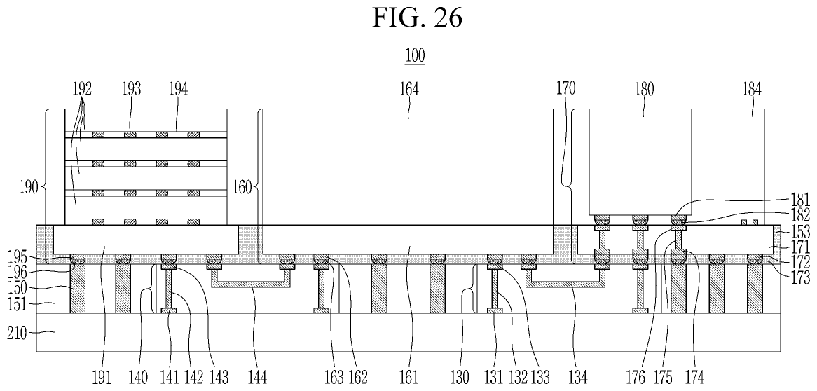

FIG. 26 is a cross-sectional view of attaching the dummy die 164 on the logic die 161, mounting the EIC 180 and the connector 184 on the PIC 171, and stacking the core dies 192 on the buffer dies 191.

Referring to FIG. 26, the dummy die 164 is attached on the logic die 161. In an embodiment, the dummy die 164 is attached using an adhesive member. In an embodiment, the adhesive member may include an adhesive tape, silver paste (Ag paste), epoxy resin, or polyimide. In an embodiment, the dummy die 164 is attached using a thermal interface material (TIM). In an embodiment, the TIM may include thermal paste, thermal pad, a phase change material (PCM), or a metal material. In an embodiment, the TIM may include grease.

The EIC 180 and the connector 184 are mounted on the PIC 171. The EIC 180 is placed on the PIC 171 by flip chip bonding. Each of the fourth connection members 182 of the EIC 180 is disposed to be electrically connected to each of the third through-hole silicon vias 175.

The core dies 192 are stacked on the buffer dies 191. The core dies 192 are stacked on the buffer die 191 using interconnection members 193, and an insulation member 194 is disposed between the buffer die 191 and the stacked core dies 192 and between the respective stacked core dies 192, thereby surrounding each of the interconnection members 193. In an embodiment, the interconnection member 193 may include a micro bump. In an embodiment, the interconnection member 193 may include or may be formed of copper. In an embodiment, the insulation member 194 may include or may be a non-conductive film (NCF).

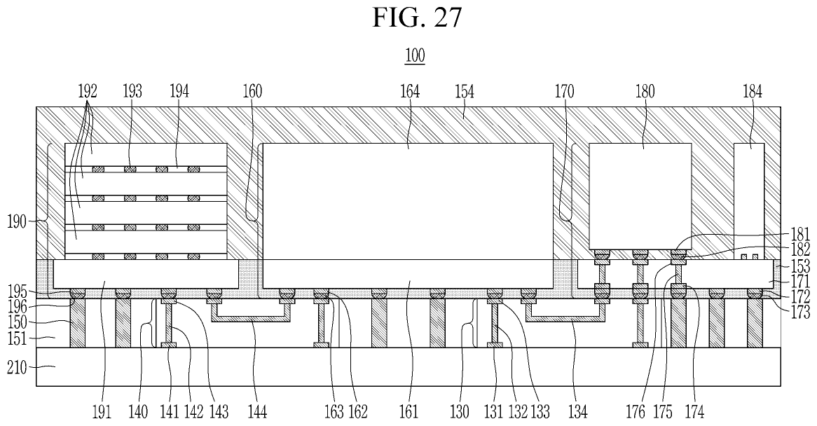

FIG. 27 is a cross-sectional view of molding the dummy die 164, the EIC 180, the connector 184, and the stacked core dies 192 with a sixth molding member 154 on the fifth molding member 153.

Referring to FIG. 27, the dummy die 164, the EIC 180, the connector 184, and the stacked core dies 192 are molded with the sixth molding member 154 on the fifth molding member 153. In an embodiment, the molding process with the sixth molding member 154 may include a compression molding or transfer molding process. In an embodiment, the sixth molding member 154 may include or may be formed of an epoxy molding compound (EMC).

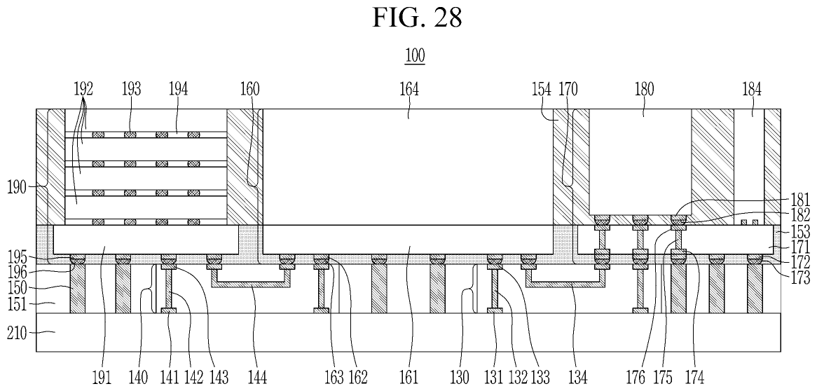

FIG. 28 is a cross-sectional view of planarizing the sixth molding member 154.

Referring to FIG. 28, the CMP is performed to level the upper surface of the sixth molding member 154. The CMP process is applied to planarize the upper surface of the sixth molding member 154. After performing the CMP process, the upper surfaces of the dummy die 164, the EIC 180, the connector 184, and the stacked core dies 192 are exposed. In this case, the levels of the upper surfaces of the dummy die 164, the EIC 180, the connector 184, and the stacked core dies 192 are all the same.

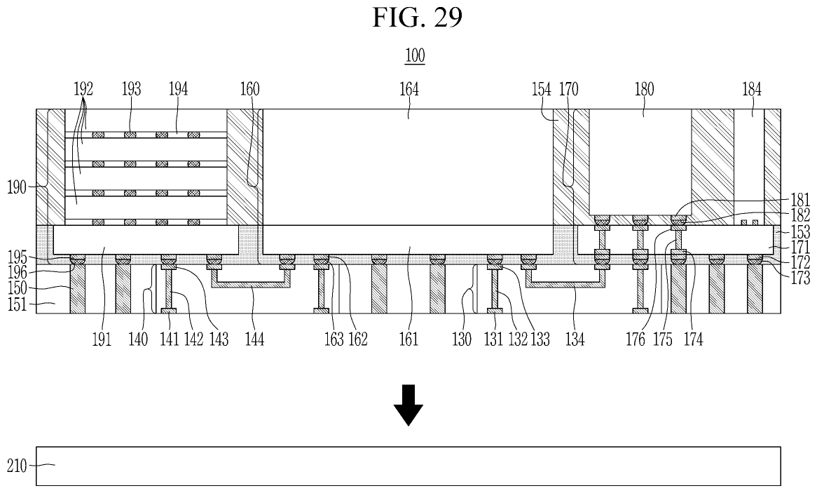

FIG. 29 is a cross-sectional view of removing the carrier 210 from the bottom surface of the first molding member 151.

Referring to FIG. 29, the carrier 210 is removed from the bottom surface of the first molding member 151.

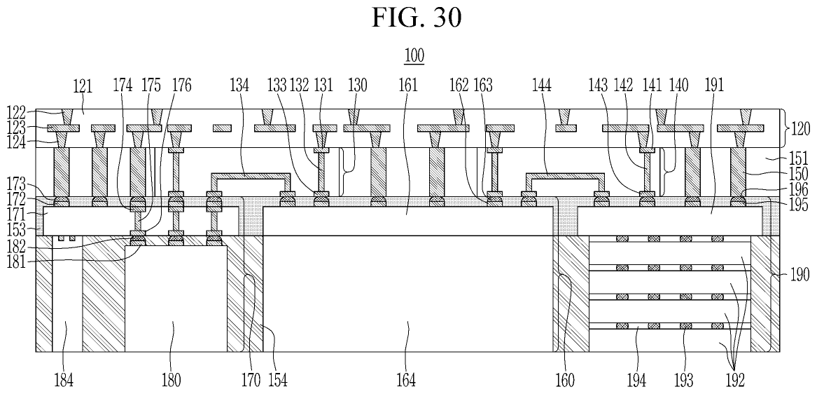

FIG. 30 is a cross-sectional view of forming the redistribution structure 120 on the first bridge die 130, the second bridge dies 140, the conductive posts 150, and the first molding member 151.

Referring to FIG. 30, an intermediate product of semiconductor package 100 is placed upside down, and the redistribution structure 120 is formed on the first bridge die 130, the second bridge dies 140, the conductive posts 150, and the first molding member 151. According to the present disclosure, since the dielectric material layer 121 is directly formed on the first bridge die 130, the second bridge dies 140, the conductive posts 150, and the first molding member 151, a connection member such as a micro bump and a solder bump is not used between the redistribution structure 120 and each of the first bridge die 130, the second bridge dies 140, and the conductive posts 150.

The dielectric material layer 121 is formed on the first bridge die 130, the second bridge dies 140, the conductive posts 150, and the first molding member 151. In an embodiment, the dielectric material layer 121 may include or may be formed of a photoimageable dielectric (PID) used in the redistribution process. In an embodiment, the PID may include a polyimide-based photoactive polymer, a novolac-based photoactive polymer, polybenzoxazole, a silicon-based polymer, an acrylate-based polymer, or an epoxy-based polymer. In an embodiment, the dielectric material layer 121 may include or may be formed of an inorganic dielectric material such as silicon nitride, silicon oxide, and the like. In an embodiment, the dielectric material layer 121 may be formed through a CVD, ALD, or PECVD process.

After forming the dielectric material layer 121, via holes are formed by selectively etching the dielectric material layer 121, and the via holes are filled with a conductive material, thereby forming the second redistribution vias 124. Since the second redistribution vias 124 are formed after placing an intermediate product of the semiconductor package 100 upside down, a width of the topmost portion of the second redistribution vias 124 is larger than a width of the bottommost portion thereof. In the final product, the top width of second redistribution vias 124 will be smaller than the bottom width.

Next, an additional dielectric material layer is deposited on the second redistribution vias 124 and the dielectric material layer 121. The additionally deposited dielectric material layer 121 is selectively etched to form openings, and the opening is filled with a conductive material, thereby forming the first redistribution lines 123.

Next, an additional dielectric material layer is deposited on the first redistribution lines 123 and the dielectric material layer 121. The additionally deposited dielectric material layer 121 is selectively etched to form via holes, and the via hole is filled with a conductive material, thereby forming the first redistribution vias 122. For the same reason as for the second redistribution vias 124, in the final product, the top width of first redistribution vias 122 will be smaller than the bottom width. For example, the dielectric material layer 121 in the final product may be formed by depositing a dielectric material layer multiple times (e.g., three times).

In an embodiment, the first redistribution vias 122, the first redistribution lines 123, and the second redistribution vias 124 may include or may be formed of at least one of copper, aluminum, tungsten, nickel, gold, tin, titanium, and an alloy thereof. In an embodiment, the first redistribution vias 122, the first redistribution lines 123, and the second redistribution vias 124 may be formed by performing an electrolytic plating process after forming a seed metal layer. In an embodiment, the first redistribution vias 122, the first redistribution lines 123, and the second redistribution vias 124 may be formed by performing a sputtering process.

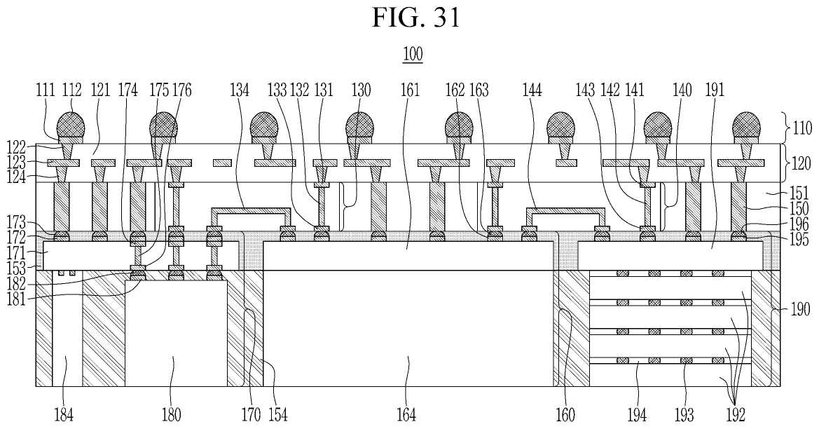

FIG. 31 is a cross-sectional view of forming the external connection structure 110 on the bottom surface of the redistribution structure 120.

Referring to FIG. 31, the external connection structure 110 is formed on the bottom surface of the redistribution structure 120. The conductive pads 111 are formed below the first redistribution vias 122 of the redistribution structure 120, and the external connection members 112 are formed below the conductive pads 111. In an embodiment, the conductive pad 111 may include or may be formed of at least one of copper, nickel, zinc, gold, silver, platinum, palladium, chromium, titanium, and an alloy thereof. In an embodiment, the external connection member 112 may include or may be formed of at least one of tin, silver, lead, nickel, copper, and an alloy thereof. In an embodiment, the conductive pad 111 may be formed by performing a sputtering process, or an electrolytic plating process after forming a seed metal layer.

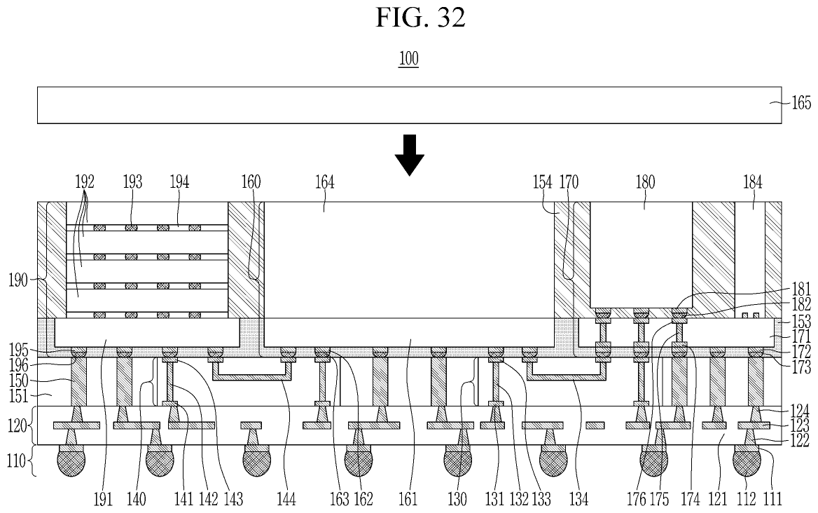

FIG. 32 is a cross-sectional view of attaching the heat dissipation structure 165 on the semiconductor die 160, the optical engine 170, and the memory stacking structures 190.

Referring to FIG. 32, the heat dissipation structure 165 is attached on the semiconductor die 160, the optical engine 170, and the memory stacking structures 190. In an embodiment, the heat dissipation structure 165 is attached using an adhesive member. In an embodiment, the adhesive member may include an adhesive tape, silver paste (Ag paste), epoxy resin, or polyimide. In an embodiment, the heat dissipation structure 165 is attached using a thermal interface material (TIM). In an embodiment, the TIM may include thermal paste, thermal pad, a phase change material (PCM), or a metal material. In an embodiment, the TIM may include grease.

While this invention has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A semiconductor package comprising:
a redistribution structure;
a semiconductor die on the redistribution structure;
one or more memory stacking structures disposed on the redistribution structure, wherein the one or more memory stacking structures and the semiconductor die are arranged side by side on the redistribution structure;
an optical engine disposed on the redistribution structure, wherein the optical engine and the semiconductor die are arranged side by side on the redistribution structure; and
a heat dissipation structure on the semiconductor die, the one or more memory stacking structures, and the optical engine, wherein levels of upper surfaces of the semiconductor die, the one or more memory stacking structures, and the optical engine are the same.

2. The semiconductor package of claim 1, wherein:
the optical engine is disposed next to a first side of the semiconductor die, and
the one or more memory stacking structures are disposed next to a second side of the semiconductor die other than the first side of the semiconductor die.

3. The semiconductor package of claim 1,
wherein the semiconductor die comprises a logic die and a dummy die on the logic die.

4. The semiconductor package of claim 3,
wherein the logic die comprises an XPU.

5. The semiconductor package of claim 3,
wherein the logic die comprises at least one of a central processing unit and a graphic processing unit.

6. The semiconductor package of claim 3,
wherein the dummy die comprises silicon or metal.

7. The semiconductor package of claim 3,
wherein a bottom surface of the dummy die contacts an upper surface of the logic die.

8. The semiconductor package of claim 1,
wherein the heat dissipation structure comprises silicon or metal.

9. The semiconductor package of claim 1,
wherein a bottom surface of the heat dissipation structure contacts an upper surface of each of the semiconductor die, the one or more memory stacking structures, and the optical engine.

10. A semiconductor package comprising:
a redistribution structure;
a first bridge die and one or more second bridge dies on the redistribution structure;
a plurality of conductive posts disposed on the redistribution structure, wherein the plurality of conductive posts, the first bridge die, and the one or more second bridge dies are arranged side by side on the redistribution structure;
a first molding member disposed on the redistribution structure and covering the first bridge die, the one or more second bridge dies, and the plurality of conductive posts;
a semiconductor die on the first molding member;
an optical engine disposed on the first molding member, wherein the optical engine and the semiconductor die are arranged side by side on the first molding member, and wherein the first bridge die electrically connects the semiconductor die to the optical engine;
one or more memory stacking structures disposed on the first molding member, wherein the one or more memory stacking structures and the semiconductor die are arranged side by side on the first molding member and the one or more second bridge dies electrically connect the semiconductor die to the one or more memory stacking structures;
a second molding member disposed on the first molding member and covering the semiconductor die, the one or more memory stacking structures, and the optical engine; and
a heat dissipation structure on the semiconductor die, the one or more memory stacking structures, and the optical engine, wherein upper surfaces of the semiconductor die, the one or more memory stacking structures, and the optical engine are all the same.

11. The semiconductor package of claim 10,
wherein the first bridge die and the one or more second bridge dies are silicon bridges.

12. The semiconductor package of claim 10,
wherein the optical engine comprises a photonic integrated circuit and an electron integrated circuit on the photonic integrated circuit.

13. The semiconductor package of claim 12, wherein:
the photonic integrated circuit comprises a plurality of through-hole silicon vias, and
the plurality of through-hole silicon vias are electrically connected to the electron integrated circuit.

14. The semiconductor package of claim 13, wherein:
a first through-hole silicon via of the plurality of through-hole silicon vias is electrically connected to one of the plurality of conductive posts, and
a second through-hole silicon via of the plurality of through-hole silicon vias are connected to the first bridge die.

15. The semiconductor package of claim 12, wherein:
the optical engine further comprises a connector, and
the connector is connected to an external optical fiber.

16. The semiconductor package of claim 10,
wherein the one or more memory stacking structures are high-bandwidth memories.

17. The semiconductor package of claim 16,
wherein each of the high-bandwidth memories comprises a buffer die and core dies stacked on the buffer die.

18. The semiconductor package of claim 10, wherein:
the semiconductor die comprises a logic die and a dummy die on the logic die,
the optical engine comprises a photonic integrated circuit and an electronic integrated circuit on the photonic integrated circuit,
the one or more memory stacking structures comprise a buffer die and core dies stacked on the buffer die, and
levels of upper surfaces of the logic die, the photonic integrated circuit, and the buffer die are the same.

19. A manufacturing method of a semiconductor package comprising:
forming a plurality of conductive posts on a carrier;
mounting a first bridge die and one or more second bridge dies on the carrier;
molding the first bridge die, the one or more second bridge dies, and the plurality of conductive posts with a first molding member, wherein the first molding member is disposed on the carrier;
mounting a semiconductor die, one or more memory stacking structures, and an optical engine on the first bridge die, the one or more second bridge dies, and the plurality of conductive posts, wherein the first bridge die electrically connects the semiconductor die to the optical engine, the one or more second bridge dies electrically connect the semiconductor die to the one or more memory stacking structures, and levels of upper surfaces of the semiconductor die, the one or more memory stacking structures, and the optical engine are the same;
molding the semiconductor die, the one or more memory stacking structures, and the optical engine with a second molding member, wherein the second molding member is disposed on the first molding member;
removing the carrier to expose a bottom surface of the first bridge die, bottom surfaces of the one or more second bridge dies, and bottom surfaces of the plurality of conductive posts;
forming a redistribution structure on the bottom surface of the first bridge die, the bottom surfaces of the one or more second bridge dies, and the bottom surfaces of the plurality of conductive posts; and
attaching a heat dissipation structure on the semiconductor die, the one or more memory stacking structures, and the optical engine.

20. The manufacturing method of the semiconductor package of claim 19, further comprising:
performing a chemical mechanical polishing process on the second molding member after the molding of the semiconductor die, the one or more memory stacking structures, and the optical engine with the second molding member.
